(19) United States
(12) Patent Application Publication
(10) Pub. No.: US 2010/0044708 A1
(43) Pub. Date: Feb. 25, 2010

(54) THIN FILM TRANSISTOR, PIXEL STRUCTURE AND FABRICATION METHODS THEREOF

(75) Inventors: Heng-Chang Lin, Taichung City (TW); Chun-Jen Ma, Taichung City (TW); Yi-Ling Hung, Kaohsiung City (TW); Teng-Yuan Hsu, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taoyuan (TW)

(21) Appl. No.: 12/258,459

(22) Filed: Oct. 27, 2008

(30) Foreign Application Priority Data
Aug. 19, 2008 (TW) 97131642

(51) Int. Cl. H01L 33/00; H01L 21/00

(52) U.S. Cl. 257/59; 438/30; 257/E21.001; 257/E33.001

(57) ABSTRACT

A fabrication method of a thin film transistor includes providing a substrate at first. Thereafter, a first gate is formed on the substrate. An insulator is then formed to cover the first gate and a portion of the substrate. After that, a channel structure is formed on the insulator above the first gate. In addition, a metal layer is formed to cover the channel structure and a portion of the insulator. Next, the metal layer is patterned, and at least the metal layer on two sidewalls of the channel structure is retained to form a source and a drain, respectively. Moreover, a passivation layer is formed to at least cover the source, the drain and a portion of the insulator.

### CROSS-REFERENCE TO RELATED APPLICATION

This application claims the priority benefit of Taiwan application serial no. 97131642, filed on Aug. 19, 2008. The entirety of the above-mentioned patent application is hereby incorporated by reference herein and made a part of specification.

### BACKGROUND OF THE INVENTION

1. Field of the Invention

The present invention relates to a pixel structure and a thin film transistor (TFT) thereof. More particularly, the present invention relates to a TFT featuring favorable device characteristics, a pixel structure in which said TFT is applied, a fabrication method of the pixel structure, and a fabrication method of the TFT.

2. Description of Related Art

A liquid crystal display (LCD) is mainly composed of a TFT array substrate, a color filter substrate, and a liquid crystal layer sandwiched between said two substrates. The TFT array substrate generally includes a substrate and a plurality of TFTs formed on the substrate. Since the TFTs are one of the most important components in the LCD, display quality of the LCD inevitably relies upon whether the device characteristics of the TFTs are satisfactory or not.

FIG. 1 is a schematic cross-sectional view of a conventional TFT. Referring to FIG. 1, a conventional TFT 100 includes a substrate 102, a bottom gate 104, a gate insulator 106, a channel layer 108, an ohmic contact layer 110, a source 112, a drain 114, a passivation layer 116, and a top gate 118. The bottom gate 104 is disposed on the substrate 102, and the gate insulator 106 covers the bottom gate 104. Moreover, the channel layer 108 is disposed on the gate insulator 106 above the bottom gate 104. The ohmic contact layer 110 is disposed between the source 112 and the channel layer 108 and between the drain 114 and the channel layer 108. In addition, the passivation layer 116 covers a portion of the gate insulator 106, the channel layer 108, the source 112, and the drain 114. It is known from FIG. 1 that the top gate 118 is disposed on the passivation layer 116 above the channel layer 108, and the top gate 118 is electrically connected to the bottom gate 104 through a contact opening C disposed in the gate insulator 106 and in the passivation layer 116.

Specifically, when the TFT 100 is turned on at 20V, for example, the bottom gate 104 is coupled to one side of the channel layer 108 to form a first channel I. On the other hand, the top gate 118 is coupled to the other side of the channel layer 108, so as to form a second channel II. Note that an electric field generated between the bottom gate 104 and the channel layer 108 is affected by another electric field generated between the top gate 118 and the channel layer 108 and, therefore, the dual gate TFT 100 cannot be exercised to the maximum degree.

FIG. 2 is a schematic view of a current leakage path in the conventional TFT. Referring to FIG. 2, when a reverse bias at −5V is applied to the TFT 100 and the TFT 100 is then turned off, electrons in the first channel I and the second channel II give rise to an occurrence of a reverse current leakage L in the channel layer 108 due to the application of the reverse bias. It should be mentioned that the current leakage L would directly pose a negative impact on the device characteristics of the TFT 100, given that the current leakage L cannot be effectively restrained. As a matter of fact, said problem is in need of solution.

### SUMMARY OF THE INVENTION

In view of the foregoing, the present invention is directed to a fabrication method of a TFT. By applying the fabrication method, a TFT having favorable device characteristics can be manufactured.

The present invention is further directed to a TFT which occupies a relatively small area, has satisfactory electrical conductivity, and is capable of reducing current leakage in an effective manner.

The present invention is further directed to a fabrication method of a pixel structure. By applying the fabrication method, a pixel structure having a high aperture ratio can be manufactured.

The present invention is further directed to a pixel structure featuring a high aperture ratio.

In the present invention, a fabrication method of a TFT is provided. The fabrication method includes following steps. First, a substrate is provided. Thereafter, a first gate is formed on the substrate. An insulator is then formed to cover the first gate. Next, a channel structure is formed on the insulator. In addition, a metal layer is formed to cover the channel structure and a portion of the insulator. Thereafter, the metal layer is patterned, and at least the metal layer on two sidewalls of the channel structure is retained to form a source and a drain, respectively. Additionally, a passivation layer is formed to cover the source and the drain.

In an embodiment of the present invention, the fabrication method of the TFT further includes forming a second gate on the passivation layer above the channel structure.

In an embodiment of the present invention, a material of the second gate includes indium tin oxide (ITO), indium zinc oxide (IZO), or aluminum zinc oxide (AZO).

In an embodiment of the present invention, the channel structure includes a first semiconductor layer, a barrier layer, and a second semiconductor layer. The first semiconductor layer is disposed on the insulator, and the barrier layer is disposed between the first semiconductor layer and the second semiconductor layer.

In an embodiment of the present invention, a material of the barrier layer includes an insulating material.

In an embodiment of the present invention, a material of the barrier layer includes an insulating material and a p-type dopant.

In an embodiment of the present invention, a material of the barrier layer includes amorphous silicon and a p-type dopant.

In an embodiment of the present invention, the fabrication method of the TFT further includes forming an ohmic contact layer between the source and one of the two sidewalls of the channel structure and between the drain and the other sidewall of the channel structure.

The present invention further provides a TFT suitable for being disposed on a substrate. The TFT of the present invention includes a first gate, an insulator, a channel structure, a source, a drain, and a passivation layer. The first gate is disposed on the substrate. The insulator covers the first gate. The channel structure is disposed on the insulator. The source and the drain are respectively disposed on two sidewalls of the channel structure. Moreover, the passivation layer of the present invention at least covers the source, the drain, and a portion of the insulator.

In an embodiment of the present invention, the source and the drain are extended away from the substrate.

In an embodiment of the present invention, the TFT further includes an ohmic contact layer disposed between the source and one of the two sidewalls of the channel structure and disposed between the drain and the other sidewall of the channel structure.

In an embodiment of the present invention, the TFT further includes a second gate disposed on the passivation layer above the channel structure.

In an embodiment of the present invention, a material of the second gate includes ITO, IZO, or AZO.

In an embodiment of the present invention, the channel structure includes a first semiconductor layer, a barrier layer, and a second semiconductor layer. The first semiconductor layer is disposed on the insulator, and the barrier layer is disposed between the first semiconductor layer and the second semiconductor layer.

In an embodiment of the present invention, a material of the barrier layer includes an insulating material.

In an embodiment of the present invention, a material of the barrier layer includes an insulating material and a p-type dopant.

In an embodiment of the present invention, a material of the barrier layer includes amorphous silicon and a p-type dopant.

The present invention further provides a fabrication method of a pixel structure. The fabrication method includes following steps. First, a substrate is provided. Next, a first gate and a scan line are formed on the substrate, and the first gate is electrically connected to the scan line. An insulator is then formed to cover the first gate, the scan line, and a portion of the substrate. After that, a channel structure is formed on the insulator. Thereafter, a metal layer is formed to cover the channel structure. The metal layer is then patterned to form a data line. Besides, at least the metal layer on two sidewalls of the channel structure is retained to form a source and a drain, respectively. The source is electrically connected to the data line. Moreover, a passivation layer is formed to at least cover the source, the drain, the data line, and a portion of the insulator. Next, a pixel electrode is formed on the passivation layer. Here, the pixel electrode is electrically connected to the drain through a first contact opening of the passivation layer.

In an embodiment of the present invention, a second gate is simultaneously formed during the formation of the pixel electrode. The second gate is at least disposed on the passivation layer above the channel structure and is partially extended above the scan line. Besides, the second gate is electrically connected to the scan line through a second contact opening of the insulator and the passivation layer.

In an embodiment of the present invention, a material of the second gate includes ITO, IZO, or AZO.

In an embodiment of the present invention, the channel structure includes a first semiconductor layer, a barrier layer, and a second semiconductor layer. The first semiconductor layer is disposed on the insulator, and the barrier layer is disposed between the first semiconductor layer and the second semiconductor layer.

In an embodiment of the present invention, a material of the barrier layer includes an insulating material.

In an embodiment of the present invention, a material of the barrier layer includes an insulating material and a p-type dopant.

In an embodiment of the present invention, a material of the barrier layer includes amorphous silicon and a p-type dopant.

In an embodiment of the present invention, the fabrication method of the pixel structure further includes forming an ohmic contact layer between the source and one of the two sidewalls of the channel structure and between the drain and the other sidewall of the channel structure.

The present invention further provides a pixel structure suitable for being disposed on a substrate. The pixel structure of the present invention includes a first gate, a scan line, an insulator, a channel structure, a data line, a source, a drain, a passivation layer, and a pixel electrode. The first gate is disposed on the substrate. The scan line is disposed on the substrate and is electrically connected to the first gate. Besides, the insulator covers the first gate, the scan line, and a portion of the substrate. The channel structure is disposed on the insulator above the first gate. In addition, the data line is disposed on the insulator. The source and the drain of the present invention are respectively disposed on two sidewalls of the channel structure. The passivation layer at least covers the source, the drain, the data line, and a portion of the insulator. The pixel electrode of the present invention is disposed on the passivation layer. Here, the pixel electrode is electrically connected to the drain through a first contact opening of the passivation layer.

In an embodiment of the present invention, the source and the drain are extended away from the substrate.

In an embodiment of the present invention, the pixel structure further includes a second gate. The second gate is disposed on the passivation layer above the channel structure and is partially extended above the scan line. Besides, the second gate is electrically connected to the scan line through a second contact opening of the insulator and the passivation layer.

In an embodiment of the present invention, a material of the second gate includes ITO, IZO, or AZO.

In an embodiment of the present invention, the channel structure includes a first semiconductor layer, a barrier layer, and a second semiconductor layer. The first semiconductor layer is disposed on the insulator, and the barrier layer is disposed between the first semiconductor layer and the second semiconductor layer.

In an embodiment of the present invention, a material of the barrier layer includes an insulating material.

In an embodiment of the present invention, a material of the barrier layer includes an insulating material and a p-type dopant.

In an embodiment of the present invention, a material of the barrier layer includes amorphous silicon and a p-type dopant.

In an embodiment of the present invention, the pixel structure further includes an ohmic contact layer disposed between the source and one of the two sidewalls of the channel structure and disposed between the drain and the other sidewall of the channel structure.

In the fabrication method of the TFT according to the present invention, the source and the drain are formed on the two sidewalls of the channel structure, such that the source and the drain are extended away from the substrate. Therefore, an area occupied by the TFT of the present invention can be significantly reduced, and an overlap region of the source, the drain, and the first gate can be also decreased, thereby leading to a reduction of the occurrence of a gate-drain capacitance Cgd in the TFT. Moreover, two channels can be formed in the channel structure of the present invention for achieving a relatively favorable conductivity. Additionally, the TFT of the present invention can be applied to the pixel structure in the fabrication method of the pixel structure according to the present invention. Thus, the pixel structure of the present invention has a relatively high aperture ratio.

In order to make the aforementioned and other features and advantages of the present invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic cross-sectional view of a conventional TFT.

FIG. 2 is a schematic view of a current leakage path in the conventional TFT.

FIGS. 3A through 3F are cross-sectional views illustrating a fabricating process of a pixel structure according to a first embodiment of the present invention.

FIGS. 4A through 4D are top views illustrating the fabricating process of the pixel structure according to the first embodiment of the present invention.

FIGS. 5A through 5G are cross-sectional views illustrating a fabricating process of a pixel structure according to a second embodiment of the present invention.

FIGS. 6A through 6D are top views illustrating the fabricating process of the pixel structure according to the second embodiment of the present invention.

### DESCRIPTION OF EMBODIMENTS

### First Embodiment

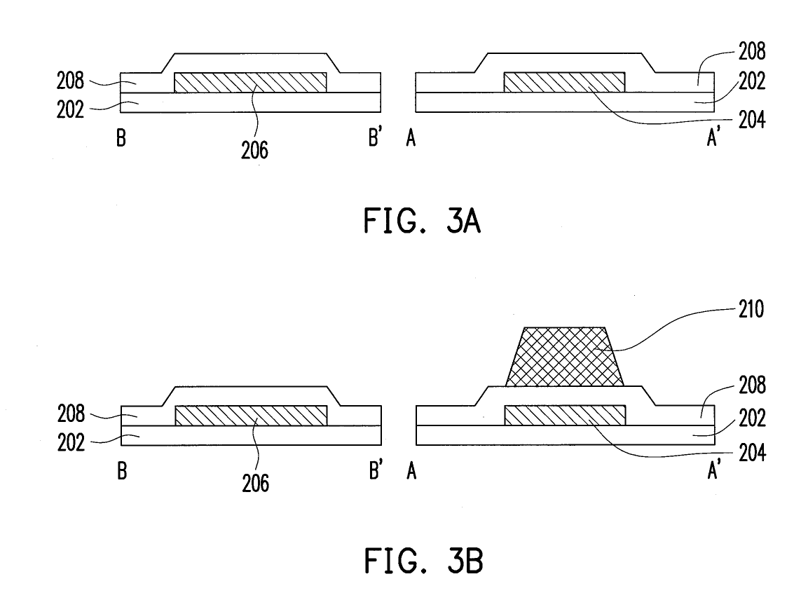

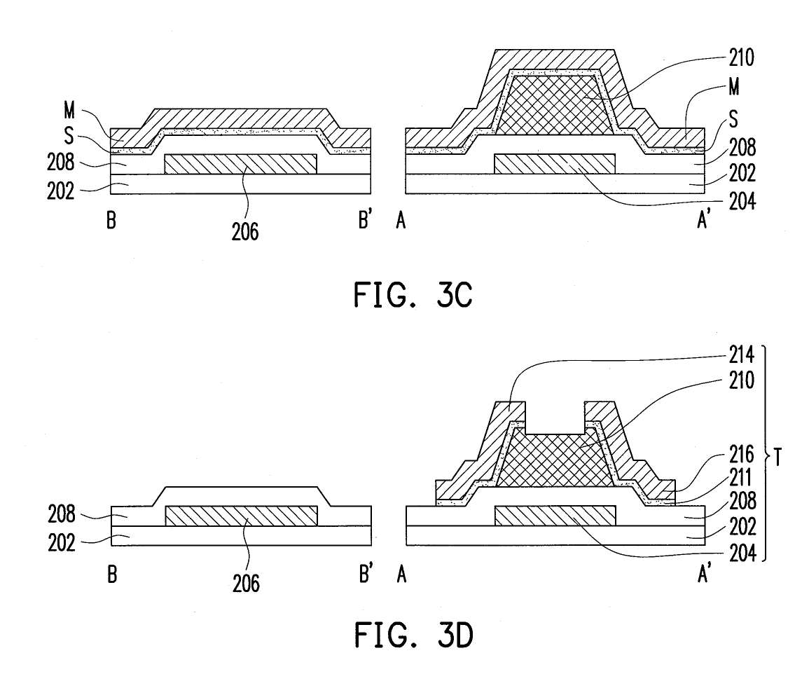

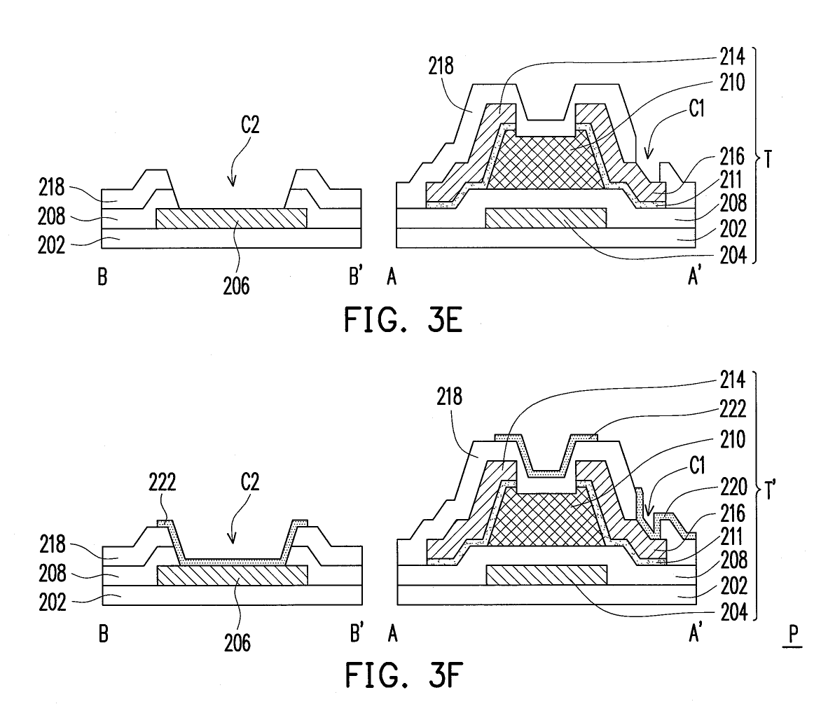

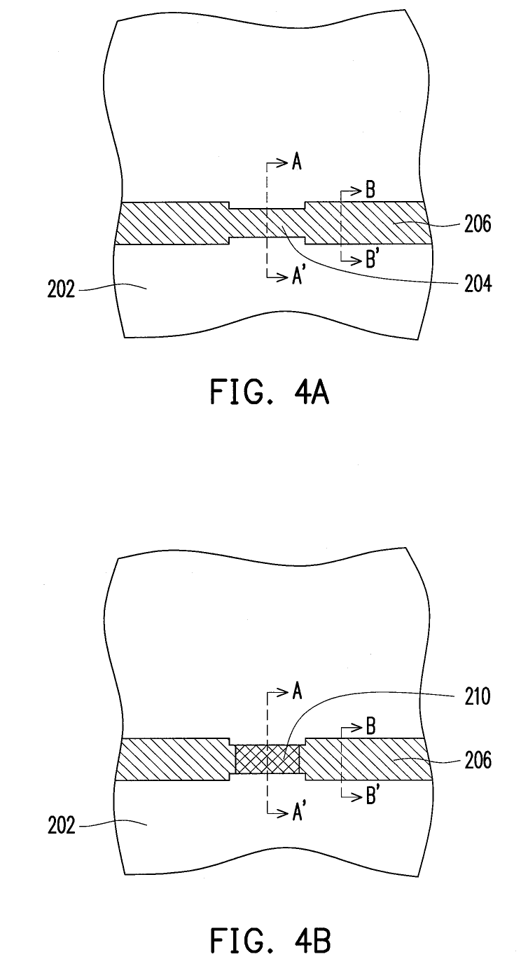

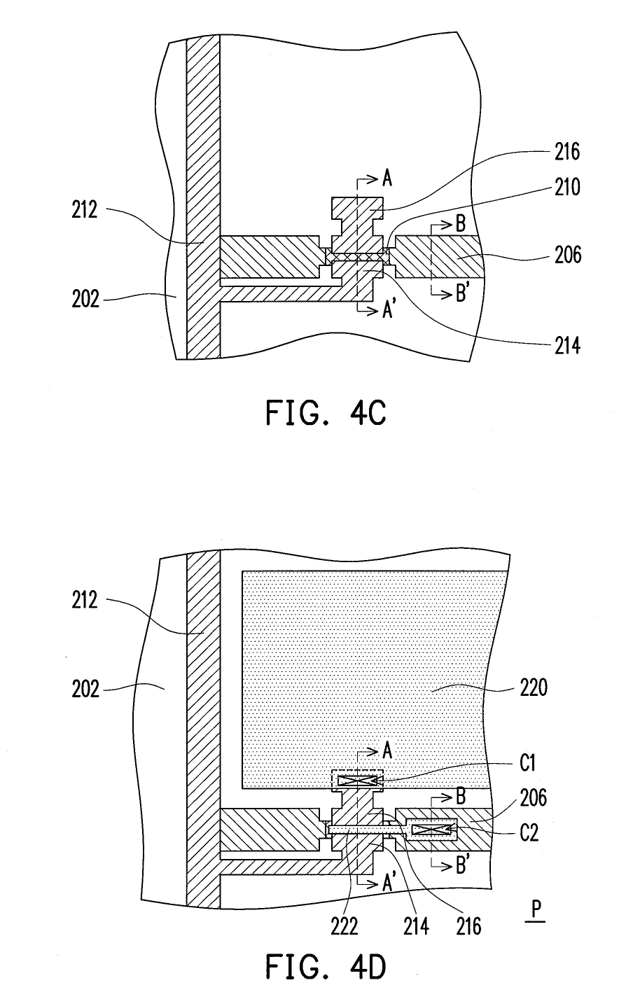

FIGS. 3A through 3F are cross-sectional views illustrating a fabricating process of a pixel structure according to a first embodiment of the present invention. FIGS. 4A through 4D are top views illustrating the fabricating process of the pixel structure according to the first embodiment of the present invention. Referring to FIGS. 3A and 4A, a fabrication method of the pixel structure of the present invention includes following steps. First, a substrate 202 is provided. Next, a first gate 204 and a scan line 206 are formed on the substrate 202, and the first gate 204 is electrically connected to the scan line 206. Certainly, it should be known to people skilled in the pertinent art that the first gate 204 can be also formed by extending a portion of the scan line 206 outward. The shape of the first gate 204 as depicted in FIG. 4A is merely illustrative and should not be construed as a limitation of the present invention.

Specifically, a metal material can be deposited on the substrate 202 to form the first gate 204 and the scan line 206 by performing a physical vapor deposition (PVD) process, for example. The metal material is then patterned with use of a photomask, such that the fabrication of the first gate 204 and the scan line 206 is completed. The aforesaid metal material includes a low electrical resistance material, such as aluminum, gold, copper, molybdenum, chromium, a combination thereof, and an alloy thereof, for example.

Next, an insulator 208 is formed to cover the first gate 204, the scan line 206, and a portion of the substrate 202. A material of the insulator 208 is, for example, silicon nitride (SiNe) or silicon oxide (SiOₓ). Note that the insulator 208 is not depicted in FIG. 4A but merely illustrated in FIG. 3A for the purpose of clarity.

Thereafter, referring to FIGS. 3B and 4B, a channel structure 210 is formed on the insulator 208 above the first gate 204. In general, an amorphous silicon material can be deposited on the substrate 202 to form the channel structure 210 by performing a chemical vapor deposition (CVD) process, for example. After that, the amorphous silicon material deposited on the substrate 202 is patterned by a photomask process, so as to complete the fabrication of the channel structure 210. It should be mentioned that the channel structure 210 not only can be formed by depositing a single-layered amorphous silicon material but also can have a multi-layered structure, which is elaborated in a second embodiment hereinafter.

Next, as shown in FIG. 3C, to reduce the contact resistance between a semiconductor material and the metal material, a doped semiconductor material layer S and a metal layer M are sequentially formed on the channel structure 210 and a portion of the insulator 208 according to an embodiment of the present invention. The doped semiconductor material layer S can be formed by implementing the CVD process, while the metal layer M can be formed by performing the PVD process.

Afterwards, referring to FIGS. 3D and 4C, the metal layer M and the doped semiconductor material layer S are patterned, such that a source 214 and a drain 216 are formed by one portion of the metal layer M, and that a data line 212 is formed by the other portion of the metal layer M. The source 214 is electrically connected to the data line 212. On the other hand, after the doped semiconductor material layer S is patterned, at least an ohmic contact layer 211 is formed between the source 214 and one sidewall of the channel structure 210 and between the drain 216 and the other sidewall of the channel structure 210. So far, the first gate 204, the insulator 208, the channel structure 210, the ohmic contact layer 211, the source 214, and the drain 216 initially constitute a TFT T of the present invention.

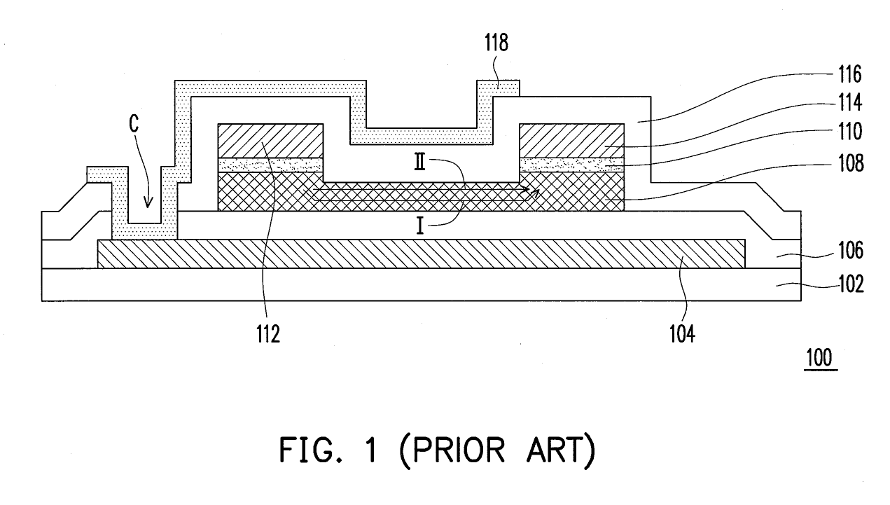

Note that the source 214 and the drain 216 indicated in FIG. 3D are extended along the two sidewalls of the channel structure 210 in an upward direction away from the substrate 202. As such, an overlap region of the source 214, the drain 216, and the first gate 204 can be significantly reduced according to the present invention. In FIG. 1, the conventional source 112 and the conventional drain 114 are extended in parallel to the substrate 102. Thereby, an area occupied by the conventional TFT 100 cannot be effectively reduced, and neither can the gate-drain parasitic capacitance. In comparison with the conventional TFT 100, the TFT T of the present invention has a significantly reduced gate-drain parasitic capacitance (Cgd). Hence, the TFT T of the present invention has favorable device characteristics. In addition, the area occupied by the entire TFT T can be also reduced in an effective manner.

Next, referring to FIG. 3E, a passivation layer 218 is formed to at least cover the data line 212, the source 214, the drain 216, a portion of the insulator 208, and a portion of the channel structure 210. Here, the passivation layer 218 has a first contact opening C1 for exposing a portion of the drain 216. Besides, the insulator 208 and the passivation layer 218 have a second contact opening C2 for exposing a portion of the scan line 206.

Next, referring to FIGS. 3F and 4D, a pixel electrode 220 is formed on the passivation layer 218. The pixel electrode 220 is electrically connected to the drain 216 through the first contact opening C1 of the passivation layer 218. Up to here, a pixel structure P of the present invention is completely fabricated. Since the area occupied by the TFT T of the present invention can be significantly reduced, an aperture ratio of the pixel structure P can be effectively improved according to the present invention.

Note that a second gate 222 can be selectively formed during the formation of the pixel electrode 220. A material of the second gate 222 is the same as the material of the pixel electrode 220, such as ITO, IZO, or AZO. The second gate 222 is at least positioned on the passivation layer 218 above the channel structure 210. Besides, a portion of the second gate 222 is extended above the scan line 206 and is electrically connected to the scan line 206 through the second contact opening C2 of the insulator 208 and the passivation layer 218.

The first gate 204, the insulator 208, the channel structure 210, the ohmic contact layer 211, the source 214, the drain 216, and the second gate 222 can together constitute the dual gate TFT T. As the TFT T is turned on, the first gate 204 is coupled to a side of the channel structure 210, while the second gate 222 is coupled to the other side of the channel structure 210. As such, two channels can be formed, and the TFT T can then be equipped with satisfactory conductivity.

### Second Embodiment

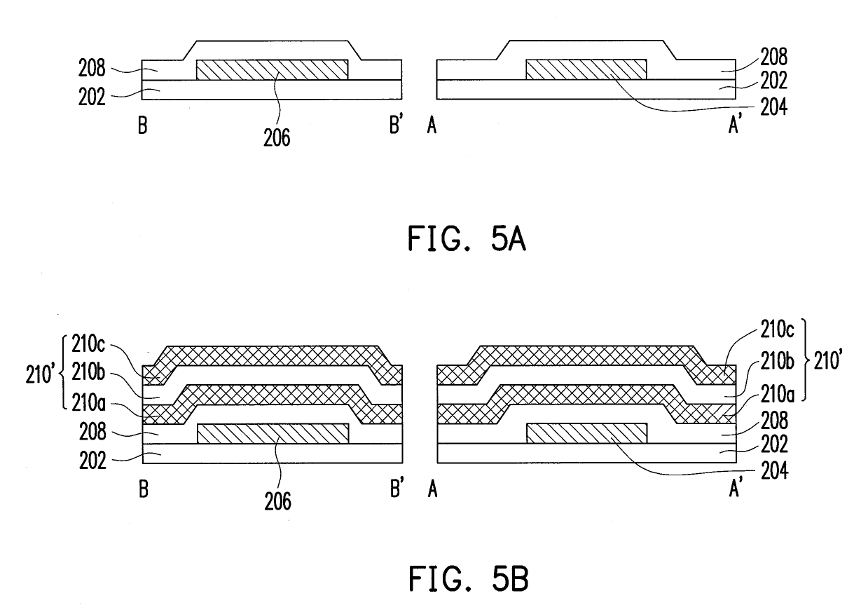

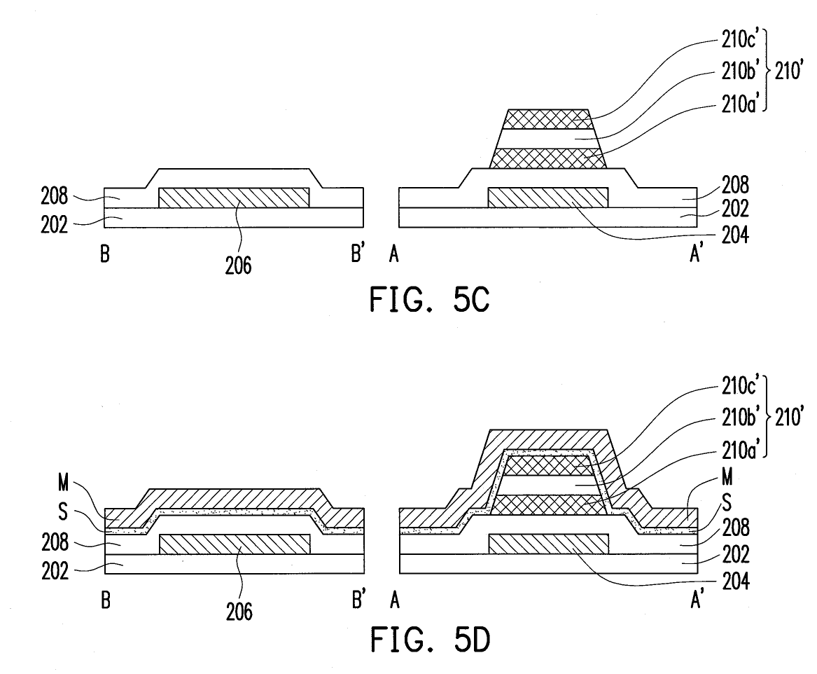

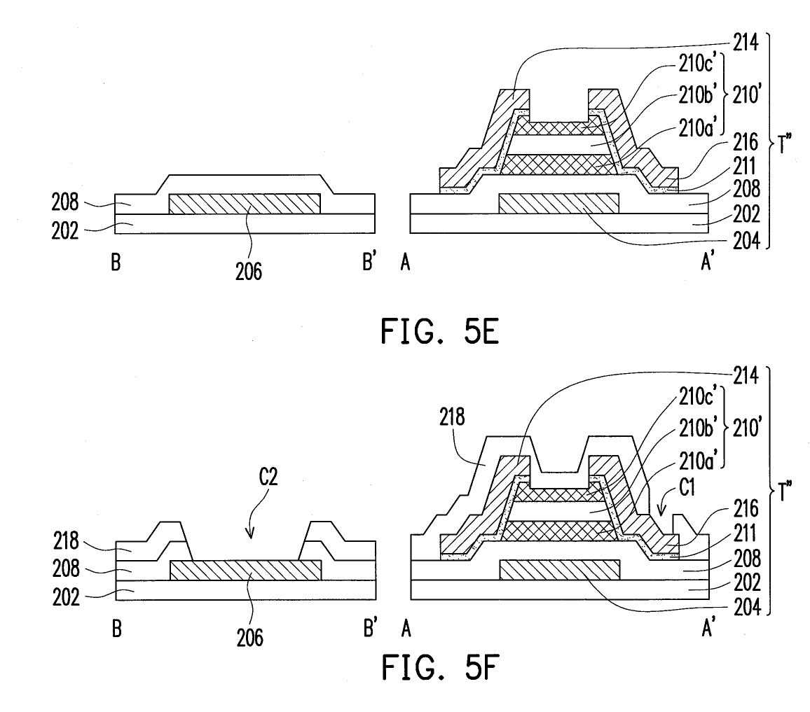

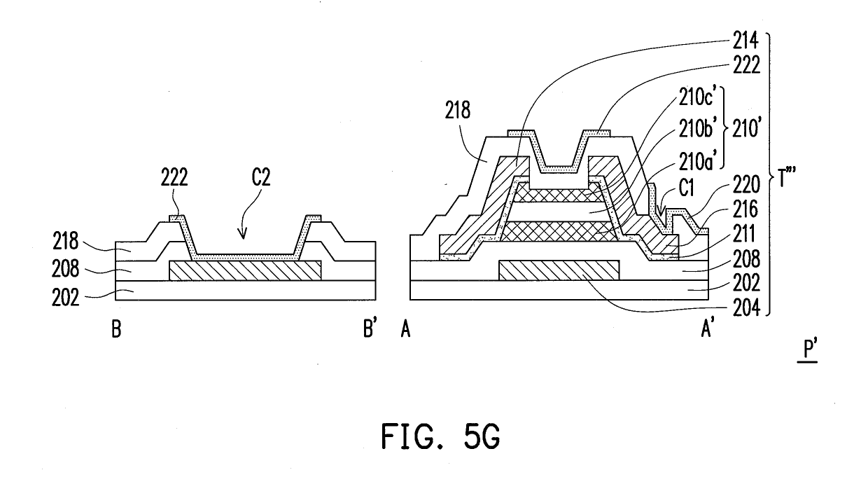

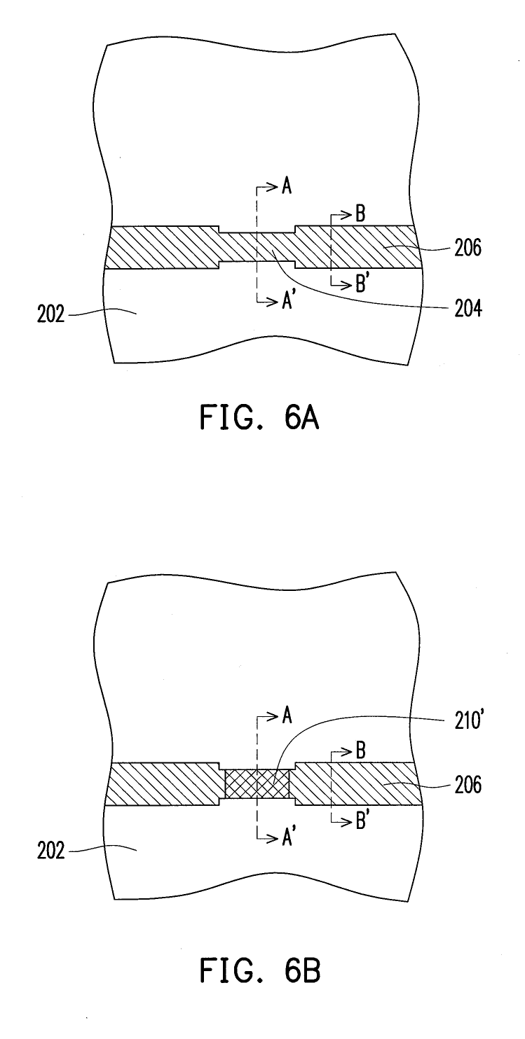

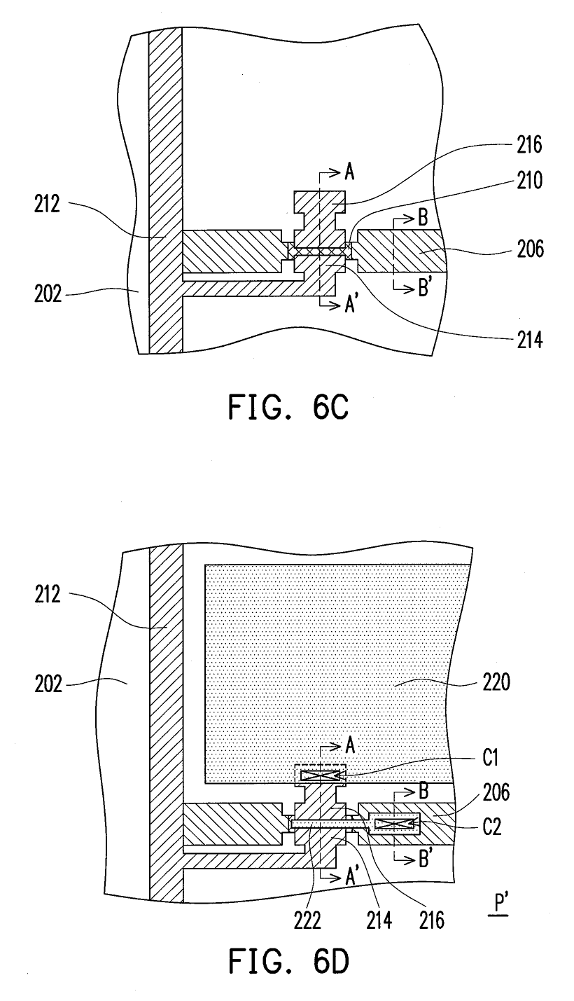

The second embodiment is similar to the first embodiment, and the difference therebetween mainly lies in the fabrication of the channel structure. FIGS. 5A through 5G are cross-sectional views illustrating a fabricating process of a pixel structure according to the second embodiment of the present invention. FIGS. 6A through 6D are top views illustrating the fabricating process of the pixel structure according to the second embodiment of the present invention. Referring to FIGS. 5A and 6A, a substrate 202 is provided at first. Next, a first gate 204 and a scan line 206 are formed on the substrate 202, and the first gate 204 is electrically connected to the scan line 206. Methods of forming the first gate 204 and the scan line 206 are similar to those discussed in the first embodiment, and therefore no further description is provided herein. After that, an insulator 208 is formed to cover the first gate 204, the scan line 206, and a portion of the substrate 202. Note that the insulator 208 is not depicted in FIG. 6A but merely illustrated in FIG. 5A for the purpose of clarity.

Thereafter, referring to FIG. 5B, a semiconductor material layer 210a, a barrier material layer 210b, and a semiconductor material layer 210c are sequentially formed on the insulator 208. A material of the barrier material layer 210b is, for example, amorphous silicon containing a p-type dopant or an insulating material containing or not containing a p-type dopant.

After that, referring to FIGS. 5C and 6B, the semiconductor material layer 210a, the barrier material layer 210b, and the semiconductor material layer 210c are patterned, so as to form a channel structure 210′ on the passivation layer 208 above the first gate 204. It should be mentioned that the channel structure 210′ includes a first semiconductor layer 210a′, a barrier layer 210b′, and a second semiconductor layer 210c′. The first semiconductor layer 210a ′ is disposed on the insulator 208, and the barrier layer 210b ′ is disposed between the first semiconductor layer 210a ′ and the second semiconductor layer 210c′.

Next, as shown in FIG. 5D, to reduce the contact resistance between a semiconductor material and a metal material, a doped semiconductor material layer S and a metal layer M are sequentially formed on the channel structure 210′ and a portion of the insulator 208 according to an embodiment of the present invention. The methods of forming the doped semiconductor material layer S and the metal layer M are similar to those discussed in the first embodiment, and therefore no further description is provided herein.

Afterwards, referring to FIGS. 5E and 6C, the metal layer M and the doped semiconductor material layer S are patterned, such that a source 214 and a drain 216 are formed by one portion of the metal layer M, and that a data line 212 is formed by the other portion of the metal layer M. The source 214 is electrically connected to the data line 212. On the other hand, after the doped semiconductor material layer S is patterned, at least an ohmic contact layer 211 is formed between the source 214 and one sidewall of the channel structure 210′ and between the drain 216 and the other sidewall of the channel structure 210′. So far, the first gate 204, the insulator 208, the channel structure 210′, the ohmic contact layer 211, the source 214, and the drain 216 initially constitute a TFT T″ of the present invention.

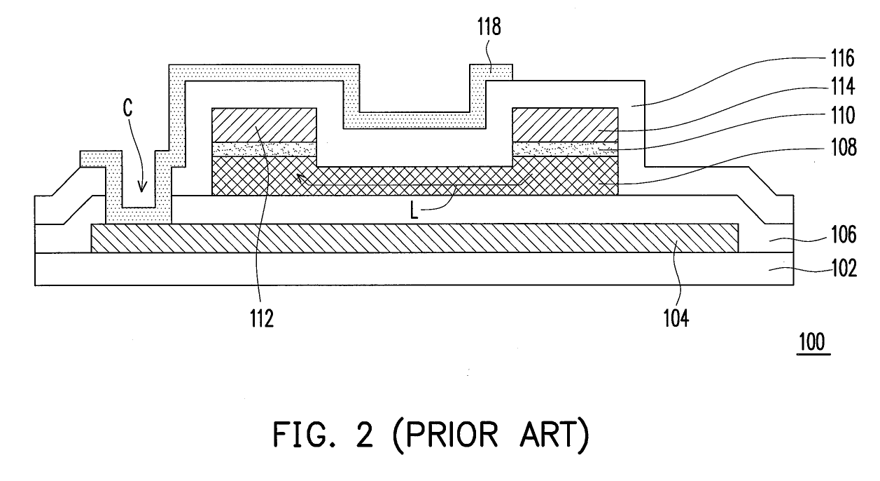

The TFT T″ depicted in FIG. 5E and the TFT T of the first embodiment have the same advantages. Note that when a reverse bias is applied to the TFT T″ and the TFT T″ is then turned off, the barrier layer 210b′ disposed in the channel structure 210′ is able to restrain the current leakage L shown in FIG. 2. To better restrain the current leakage L, the barrier layer 210b′ is, for example, made of the insulating material containing the p-type dopant or amorphous silicon containing the p-type dopant, so as to effectively restrain current leakage generated in the channel structure 210′. Hence, the TFT T″ of the present invention has favorable device characteristics.

Please refer to FIG. 5F. A passivation layer 218 is formed to at least cover the source 214, the drain 216, the data line 212, and a portion of the insulator 208. Here, the passivation layer 218 has a first contact opening C1 for exposing the drain 216. Besides, the insulator 208 and the passivation layer 218 have a second contact opening C2 for exposing a portion of the scan line 206.

Next, referring to FIGS. 5G and 6D, a pixel electrode 220 is formed on the passivation layer 218. The pixel electrode 220 is electrically connected to the drain 216 through the first contact opening C1 of the passivation layer 218. Up to here, a pixel structure P′ of the present invention is completely fabricated.

Note that a second gate 222 can be selectively formed during the formation of the pixel electrode 220. A material of the second gate 222 is the same as the material of the pixel electrode 220, such as ITO, IZO, or AZO. The second gate 222 is positioned on the passivation layer 218 above the channel structure 210′. A portion of the second gate 222 is extended above the scan line 206 and is electrically connected to the scan line 206 through the second contact opening C2 of the insulator 208 and the passivation layer 218.

It should be noted that the first gate 204, the insulator 208, the channel structure 210′, the ohmic contact layer 211, the source 214, the drain 216, and the second gate 222 can together constitute a dual gate TFT T″′″. As the TFT T′″ is turned on, the first gate 204 is coupled to the first semiconductor layer 210a′, while the second gate 222 is coupled to the second semiconductor layer 210c′. As such, the TFT T′″ can then be equipped with satisfactory conductivity. Particularly, the barrier layer 210b′ is able to prevent electric fields generated between the first gate 204 and the first semiconductor layer 210a ′ and between the second gate 222 and the second semiconductor layer 210c ′ from interacting, and thereby the TFT T′″ can be fully exercised.

To sum up, in the fabrication method of the TFT according to the present invention, the source and the drain are formed on the two sidewalls of the channel structure, such that the source and the drain are extended away from the substrate. Hence, the overlap region of the source, the drain, and the first gate can be decreased effectively, thereby restraining the occurrence of the gate-drain capacitance Cgd in the TFT in an efficacious manner. The area occupied by the TFT of the present invention can be significantly reduced as well. Moreover, two channels can be formed in the channel structure of the present invention for achieving favorable conductivity, and the current leakage can be effectively avoided by means of the barrier layer. In addition, the barrier layer can prevent the electric fields of the two channels from interacting, such that the TFT of the present invention can be fully exercised. Further, the TFT of the present invention can be applied to the pixel structure in the fabrication method of the pixel structure according to the present invention. Thus, the aperture ratio of the pixel structure is relatively high according to the present invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method of a thin film transistor, the fabrication method comprising:
providing a substrate;
forming a first gate on the substrate;
forming an insulator to cover the first gate;
forming a channel structure on the insulator;
forming a metal layer to cover the channel structure and a portion of the insulator;
patterning the metal layer and retaining the metal layer on two sidewalls of the channel structure to form a source and a drain; and
forming a passivation layer covering the source and the drain.

2. The fabrication method of the thin film transistor as claimed in claim 1, further comprising forming a second gate on the passivation layer above the channel structure.

3. The fabrication method of the thin film transistor as claimed in claim 2, wherein a material of the second gate comprises indium tin oxide, indium zinc oxide, or aluminum zinc oxide.

4. The fabrication method of the thin film transistor as claimed in claim 1, wherein the channel structure comprises a first semiconductor layer, a barrier layer, and a second semiconductor layer, the first semiconductor layer is disposed on the insulator, and the barrier layer is disposed between the first semiconductor layer and the second semiconductor layer.

5. The fabrication method of the thin film transistor as claimed in claim 4, wherein a material of the barrier layer comprises an insulating material.

6. The fabrication method of the thin film transistor as claimed in claim 4, wherein a material of the barrier layer comprises an insulating material and a p-type dopant.

7. The fabrication method of the thin film transistor as claimed in claim 4, wherein a material of the barrier layer comprises amorphous silicon and a p-type dopant.

8. The fabrication method of the thin film transistor as claimed in claim 1, further comprising forming an ohmic contact layer between the source and one of the two sidewalls of the channel structure and between the drain and the other sidewall of the channel structure.

9. A thin film transistor, suitable for being disposed on a substrate, the thin film transistor comprising:
a first gate, disposed on the substrate;
an insulator, covering the first gate;
a channel structure, disposed on the insulator;
a source and a drain, respectively disposed on two sidewalls of the channel structure; and
a passivation layer, at least covering the source, the drain, and a portion of the insulator.

10. The thin film transistor as claimed in claim 9, wherein the source and the drain are extended away from the substrate.

11. The thin film transistor as claimed in claim 9, further comprising an ohmic contact layer disposed between the source and one of the two sidewalls of the channel structure and disposed between the drain and the other sidewall of the channel structure.

12. The thin film transistor as claimed in claim 9, further comprising a second gate disposed on the passivation layer above the channel structure.

13. The thin film transistor as claimed in claim 12, wherein a material of the second gate comprises indium tin oxide, indium zinc oxide, or aluminum zinc oxide.

14. The thin film transistor as claimed in claim 9, wherein the channel structure comprises a first semiconductor layer, a barrier layer, and a second semiconductor layer, the first semiconductor layer is disposed on the insulator, and the barrier layer is disposed between the first semiconductor layer and the second semiconductor layer.

15. The thin film transistor as claimed in claim 14, wherein a material of the barrier layer comprises an insulating material.

16. The thin film transistor as claimed in claim 14, wherein a material of the barrier layer comprises an insulating material and a p-type dopant.

17. The thin film transistor as claimed in claim 14, wherein a material of the barrier layer comprises amorphous silicon and a p-type dopant.

18. A fabrication method of a pixel structure, the fabrication method comprising:
providing a substrate;
forming a first gate and a scan line on the substrate, the first gate being electrically connected to the scan line;
forming an insulator to cover the first gate, the scan line, and a portion of the substrate;
forming a channel structure on the insulator;
forming a metal layer to cover the channel structure;
patterning the metal layer to form a data line and at least retaining the metal layer on two sidewalls of the channel structure to respectively form a source and a drain, wherein the source is electrically connected to the data line;
forming a passivation layer at least covering the source, the drain, the data line, and a portion of the insulator; and
forming a pixel electrode on the passivation layer, wherein the pixel electrode is electrically connected to the drain through a first contact opening of the passivation layer.

19. The fabrication method of the pixel structure as claimed in claim 18, further comprising forming a second gate during the formation of the pixel electrode, wherein the second gate is at least disposed on the passivation layer above the channel structure and is partially extended above the scan line, and the second gate is electrically connected to the scan line through a second contact opening of the insulator and the passivation layer.

20. The fabrication method of the pixel structure as claimed in claim 19, wherein a material of the second gate comprises indium tin oxide, indium zinc oxide, or aluminum zinc oxide.

21. The fabrication method of the pixel structure as claimed in claim 18, wherein the channel structure comprises a first semiconductor layer, a barrier layer, and a second semiconductor layer, the first semiconductor layer is disposed on the insulator, and the barrier layer is disposed between the first semiconductor layer and the second semiconductor layer.

22. The fabrication method of the pixel structure as claimed in claim 21, wherein a material of the barrier layer comprises an insulating material.

23. The fabrication method of the pixel structure as claimed in claim 21, wherein a material of the barrier layer comprises an insulating material and a p-type dopant.

24. The fabrication method of the pixel structure as claimed in claim 21, wherein a material of the barrier layer comprises amorphous silicon and a p-type dopant.

25. The fabrication method of the pixel structure as claimed in claim 18, further comprising forming an ohmic contact layer between the source and one of the two sidewalls of the channel structure and between the drain and the other sidewall of the channel structure.

26. A pixel structure, suitable for being disposed on a substrate, the pixel structure comprising:
a first gate, disposed on the substrate;
a scan line, disposed on the substrate and electrically connected to the first gate;
an insulator, covering the first gate, the scan line, and a portion of the substrate;
a channel structure, disposed on the insulator;
a data line, disposed on the insulator;
a source and a drain, respectively disposed on two sidewalls of the channel structure;
a passivation layer, at least covering the source, the drain, the data line, and a portion of the insulator; and
a pixel electrode, disposed on the passivation layer, wherein the pixel electrode is electrically connected to the drain through a first contact opening of the passivation layer.

27. The pixel structure as claimed in claim 26, wherein the source and the drain are extended away from the substrate.

28. The pixel structure as claimed in claim 26, further comprising a second gate disposed on the passivation layer above the channel structure and partially extended above the scan line, wherein the second gate is electrically connected to the scan line through a second contact opening of the insulator and the passivation layer.

29. The pixel structure as claimed in claim 28, wherein a material of the second gate comprises indium tin oxide, indium zinc oxide, or aluminum zinc oxide.

30. The pixel structure as claimed in claim 26, wherein the channel structure comprises a first semiconductor layer, a barrier layer, and a second semiconductor layer, the first semiconductor layer is disposed on the insulator, and the barrier layer is disposed between the first semiconductor layer and the second semiconductor layer.

31. The pixel structure as claimed in claim 30, wherein a material of the barrier layer comprises an insulating material.

32. The pixel structure as claimed in claim 30, wherein a material of the barrier layer comprises an insulating material and a p-type dopant.

33. The pixel structure as claimed in claim 30, wherein a material of the barrier layer comprises amorphous silicon and a p-type dopant.

34. The pixel structure as claimed in claim 26, further comprising an ohmic contact layer disposed between the source and one of the two sidewalls of the channel structure and disposed between the drain and the other sidewall of the channel structure.
